(19) United States
(12) Patent Application Publication
(10) Pub. No.: US 2024/0429344 A1
(43) Pub. Date: Dec. 26, 2024

(54) N-POLAR III-NITRIDE NANOWIRE-BASED LED DEVICES

(71) Applicant: The Regents of the University of Michigan, Ann Arbor, MI (US)

(72) Inventors: Yakshita Malhotra, Ann Arbor, MI (US); Ayush Pandey, Ann Arbor, MI (US); Zetian Mi, Ann Arbor, MI (US)

(21) Appl. No.: 18/703,497

(22) PCT Filed: Oct. 24, 2022
(86) PCT No.: PCT/US2022/047566

§ 371 Date: Apr. 22, 2024

Related U.S. Application Data
(60) Provisional application No. 63/270,695, filed on Oct. 22, 2021.

(51) Int. Cl. H01L 33/00; H01L 33/06; H01L 33/08; H01L 33/24; H01L 33/32

(52) U.S. Cl. CPC H01L 33/0095; H01L 33/007; H01L 33/06; H01L 33/08; H01L 33/24; H01L 33/32

(57) ABSTRACT

A method for fabricating a light emitting diode (LED) device includes forming a nitrogen-polar (N-polar) template on a substrate, growing a first N-polar, III-nitride semiconductor segment of a nanostructure, growing a N-polar active region of the nanostructure, the N-polar active region being supported by the first N-polar, III-nitride semiconductor segment, the N-polar active region including a ternary or quaternary III-nitride semiconductor material, and growing a second N-polar, III-nitride semiconductor segment of the nanostructure, the second N-polar segment being supported by the N-polar active region.

### CROSS-REFERENCE TO RELATED APPLICATION

This application claims the benefit of U.S. provisional application entitled “N-Polar III-Nitride Nanowire-Based LED Devices,” filed Oct. 22, 2021, and assigned Ser. No. 63/270,695, the entire disclosure of which is hereby expressly incorporated by reference.

### BACKGROUND OF THE DISCLOSURE

### Field of the Disclosure

The disclosure relates generally to nanowire-based light emitting diodes.

### Brief Description of Related Technology

Submicron and nanoscale optoelectronic devices, including light emitting diodes (LEDs) devices and laser diodes, have drawn considerable attention, as they are essential for future large scale, or ultra-large-scale integration of electronic and optoelectronic devices on a single chip. To date, however, it has remained extremely challenging to achieve high efficiency micro, or nanoscale optoelectronic devices. One noticeable example is the efficiency cliff related to micro-LED devices, i.e., a drastic reduction of the device efficiency with reducing dimensions. Micro-LED devices have been considered as the essential building block for emerging virtual/augmented reality devices and systems, due to their ultrahigh brightness, low power consumption, ultrahigh integration density, superior stability, and long lifetime. Shown in FIG. 1, external quantum efficiency (EQE) in the range of 50-70% has been commonly measured for AlGaInP-based large area LEDs (lateral dimensions >100 μm), whereas the efficiency drops to negligible values for devices with lateral dimensions on the order of ten micrometers.

AlGaInP-based materials have poor charge carrier confinement, relatively long carrier diffusion length, and large surface recombination. In this regard, Ga(In)N-based heterostructures offer stronger carrier confinement, smaller carrier diffusion lengths, as well as a lower level of surface recombination velocity. However, the large lattice mismatch between InN and GaN (about 10%) has prevented the realization of high quality InGaN quantum well heterostructures emitting in the deep visible, i.e., yellow, orange, and red spectrum. As such, the efficiency of conventional InGaN quantum well LEDs decreases drastically with increasing wavelengths. Moreover, the efficiency cliff, caused by etch-induced surface damaging with reduce device size, is even more severe than AlInGaP-based red LEDs. Shown in FIG. 1 are some reported EQE values for Ga(In)N based red LEDs with various lateral dimensions. EQE up to about 20% has been reported for broad area InGaN red LEDs (dimension of about 1,000 μm), whereas an EQE value of about 0.1%, or lower being measured for devices with lateral dimensions of about 5-10 μm.

### SUMMARY OF THE DISCLOSURE

In accordance with one aspect of the disclosure, a method for fabricating a light emitting diode (LED) device includes forming a nitrogen-polar (N-polar) template on a substrate, growing a first N-polar, III-nitride semiconductor segment of a nanostructure, growing a N-polar active region of the nanostructure, the N-polar active region being supported by the first N-polar, III-nitride semiconductor segment, the N-polar active region including a ternary or quaternary III-nitride semiconductor material, and growing a second N-polar, III-nitride semiconductor segment of the nanostructure, the second N-polar segment being supported by the N-polar active region.

In accordance with another aspect of the disclosure, a method for fabricating a light emitting diode (LED) device includes growing a first III-nitride semiconductor segment, growing an active region supported by the first III-nitride semiconductor segment, the active region including a ternary or quaternary III-nitride semiconductor material, growing a second III-nitride semiconductor segment, the second III-nitride semiconductor segment being supported by the active region, and annealing the active region after growing the second III-nitride semiconductor segment.

In accordance with yet another aspect of the disclosure, a light emitting diode (LED) device includes a substrate, an N-polar, III-nitride template supported by the substrate, and a nanostructure extending outward from the substrate and supported by the N-polar, III-nitride template. The nanostructure includes a first N-polar, III-nitride semiconductor segment, a N-polar active region supported by the first N-polar, III-nitride semiconductor segment, the N-polar active region including a ternary or quaternary III-nitride semiconductor material, and a second N-polar, III-nitride semiconductor segment supported by the N-polar active region.

In accordance with still another aspect of the disclosure, a light emitting diode (LED) device includes a substrate, an N-polar, III-nitride template, and a nanostructure supported by, and extending outward from, the substrate. The nanostructure includes a first N-polar, III-nitride semiconductor segment, a N-polar active region supported by the first N-polar, III-nitride semiconductor segment, the N-polar active region including a ternary or quaternary III-nitride semiconductor material, and a second N-polar, III-nitride semiconductor segment supported by the N-polar active region. The N-polar active region has a thickness too large for formation of a quantum well.

In accordance with yet still another aspect of the disclosure, a light emitting diode (LED) device includes a substrate and a nanostructure supported by, and extending outward from, the substrate, the nanostructure including an active region, the active region being configured for red spectrum emission. The nanostructure has sub-micron lateral dimensions.

In connection with any one of the aforementioned aspects, the devices and/or methods described herein may alternatively or additionally include or involve any combination of one or more of the following aspects or features. The method further includes annealing the N-polar active region after growing the second N-polar, III-nitride semiconductor segment. Growing the N-polar active region includes implementing a growth procedure configured such that the N-polar active region includes an N-polar quantum well, an N-polar quantum disk, or an N-polar quantum dot, that emits in the red spectrum. Annealing the N-polar active region is implemented in a chamber in which the first N-polar, III-nitride semiconductor segment, the N-polar active region, and the second N-polar, III-nitride semiconductor segment are grown. Growing the first N-polar, III-nitride semiconductor segment, growing the N-polar active region, and growing the second N-polar, III-nitride semiconductor segment are performed under nitrogen-rich conditions. Growing the N-polar active region includes implementing a growth procedure configured such that the N-polar active region has red spectrum emission. The ternary or quaternary III-nitride semiconductor material is InGaN. Growing the active region includes implementing a growth procedure configured such that the active region includes an N-polar quantum well, an N-polar quantum disk, or an N-polar quantum dot, that emits in the red spectrum. Annealing the active region is implemented without removal from a growth chamber in which the active region and the second III-nitride semiconductor segment are grown. Growing the first III-nitride semiconductor segment, growing the active region, and growing the second III-nitride semiconductor segment are performed under nitrogen-rich conditions. Growing the active region includes implementing a growth procedure configured such that the active region has red spectrum emission. The ternary or quaternary III-nitride semiconductor material is InGaN. The first N-polar, III-nitride semiconductor segment and the second N-polar, III-nitride semiconductor segment include N-polar GaN. The ternary or quaternary III-nitride semiconductor material is InGaN. The ternary or quaternary III-nitride semiconductor material is InGaN with an indium composition greater than about 0.20. The N-polar active region is configured for red spectrum emission. The nanostructure has sub-micron lateral dimensions. The thickness is greater than a range from about 3 nm to about 5 nm. The active region includes a ternary or quaternary III-nitride semiconductor material. The LED device further includes an N-polar, III-nitride template disposed between the substrate and the nanostructure.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts a graphical representation of variations of peak external quantum efficiency (EQE) of some previously reported red-emitting LEDs, showing the presence of the efficiency cliff, i.e., significantly reduced efficiency with decreasing device size, in which the squares are representative of AlInGaP-based red LEDs, circles are representative of InGaN-based red LEDs, and examples from this work are indicated by solid circles.

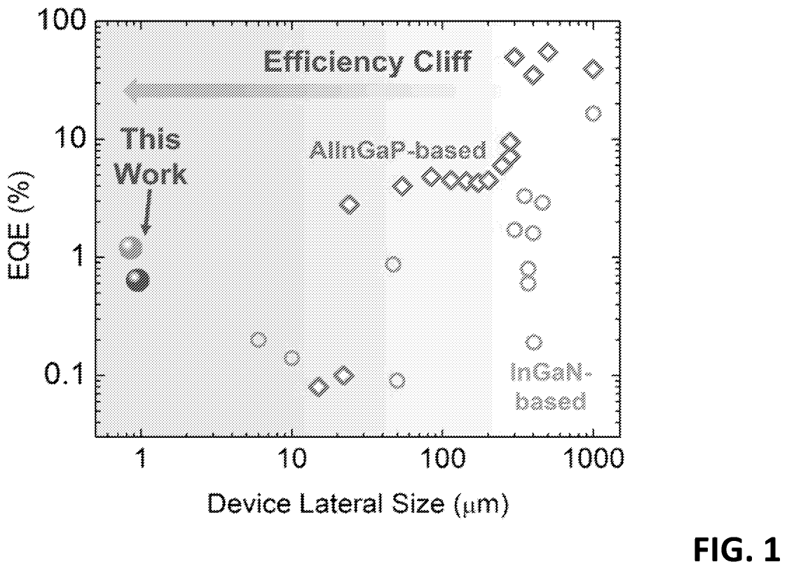

FIG. 2 depicts (a) a schematic illustration of N-polar InGaN/GaN quantum dot-in-nanowire LED heterostructures grown on N-polar GaN template on sapphire substrate in accordance with one example, and (b-c) SEM images of example N-polar InGaN/GaN nanowire arrays, showing site-controlled epitaxy and high uniformity.

FIG. 3 depicts a graphical representation of photoluminescence spectra of InGaN/GaN nanowire heterostructures measured at room-temperature for examples with and without in situ annealing (the intensity of the non-annealed example has been magnified by a factor of 5).

FIG. 4 depicts (a) a cross-sectional STEM-HAADF image of nanowires, (b) a magnified STEM-HAADF image of the InGaN active region in the nanowire shown in the middle of part (a), (c) an atomic-scale image of the InGaN active region, (d) a color mixed element map collected from a part of the nanowire with the InGaN active region included by STEM-SI using X-ray signals showing the distributions of Ga (in red—darker) and In (in green—lighter), respectively, (e) Ga and In elemental profiles along the dotted band outlined (with dashed lines) in part (d), with the different sections of the nanowire shown as the shaded regions.

FIG. 5 depicts (a) a schematic view of an example InGaN micro-LED device, showing current injection window before depositing p-metal contact, (b) an SEM image of the submicron-scale device via, with the injection window indicated by the yellow dashed curve, (c) a graphical plot of EL spectra measured for different devices, showing the tunability of the emission wavelength across the yellow-red wavelength range of the visible spectrum, and (d) J-V characteristics for example devices A and B, shown as orange (lighter) and red (darker) curves, respectively.

FIG. 6 depicts graphical representations of (a) EL spectra measured for device A from an injection current of 0.5 A/cm² to 6 A/cm², (b) EL spectra measured for device B from an injection current of 1 A/cm² to 10 A/cm², and (c-d) variation in FWHM and peak position, measured from the EL spectra for the devices at different injection currents.

FIG. 7 depicts a graphical representation of variation of the EQE with current density for Device A, in which the estimated error from measurement conditions in calculating the EQE at the low current density corresponding to the peak is approximately 15%.

FIG. 8 depicts a flow diagram of a method for fabricating a light emitting diode (LED) device in accordance with one example.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Light-emitting diode (LED) devices based on nanowires or other nanostructures configured to emit red light are described. The nanowires may be or include heterostructures having nitrogen (N)-polar III-nitride segments, including a N-polar, III-nitride active region (e.g., an InGaN active region). In some cases, the active region segment has a thickness too large to form a quantum well. The devices may be micro-scale LED (i.e., micro-LED) devices. For instance, in some cases, the devices have sub-micron lateral dimensions.

Methods for fabricating such devices are also described. In one aspect, the disclosed methods may include an annealing procedure to remove defects in the heterostructures. The annealing of the heterostructures may improve the efficiency of the disclosed devices in emissions in the red spectrum.

Although described in connection with red micro-LED devices, the disclosed methods and devices may be applied to a wide variety of LED and other optoelectronic devices.

Bottom-up InGaN nanostructures, e.g., nanowires and nanorods, offer an alternative approach to overcome the efficiency cliff of micro, or nano LEDs in the deep visible regime. The bottom-up approach has a major advantage over a top-down etching approach due to the reduced density of surface defects at the edge of the device mesa, commonly associated with plasma-based etching of nitrides. Previous studies, however, have been largely focused on InGaN nanowire devices with mixed or Ga-polarity. The device performance suffers severely from charge carrier (electron) overflow/leakage and nonradiative parasitic recombination outside of the device active region, leading to very low efficiency. Moreover, the pyramid-like morphology associated with Ga-polar nanowires makes it difficult for the fabrication of high efficiency LED devices.

These challenges can be potentially addressed by N-polar InGaN nanowires, which are characterized by uniformly flat surfaces that are compatible with planar fabrication processes. Due to the reversed polarization field in N-polar structures, electron leakage/overflow can be greatly suppressed in N-polar InGaN quantum wells/dots, compared to their Ga-polar counterparts.

Recent studies further suggested that the lateral surfaces of N-polar GaN nanowires can form a stable oxynitride layer, which can significantly reduce nonradiative surface recombination. N-polar InGaN also exhibits a higher decomposition temperature than its metal-polar counterpart, thereby allowing for the epitaxy of InGaN at higher temperatures to reduce point defect formation and/or undesired impurity incorporation.

Disclosed herein are examples of N-polar InGaN nanowire-based submicron-scale LED devices capable of operating in the deep visible regime, as well as methods of fabricating such devices. The emission wavelengths of the N-polar InGaN nanowires may be tuned. The emission wavelengths can be shifted from yellow to orange to red by varying the material fluxes and growth temperature. The luminescence efficiency can be enhanced by more than one order of magnitude through an in situ annealing process of the InGaN active region to reduce defect formation. Examples of LED devices with lateral dimensions as small as about 0.75 μm, including about 5 InGaN nanowires, were fabricated and characterized. This represents the first ever demonstration of a submicron scale red-emitting LED. A maximum external quantum efficiency of 1.2% was measured for an unpackaged device, which is over one order of magnitude higher than that of conventional InGaN quantum well red micro-LEDs. The disclosed methods provide a viable approach to overcome the efficiency cliff of optoelectronic electronic devices at the micro- or nano-scale.

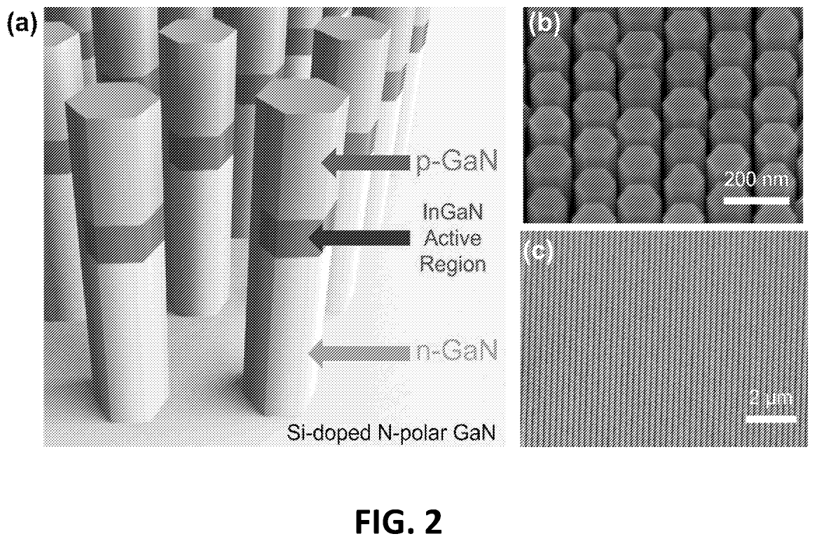

FIG. 2, part (a), schematically shows a N-polar GaN/InGaN nanowire micro-LED heterostructure in accordance with one example. In this case, the heterostructure includes a Si-doped GaN (n-type GaN), InGaN quantum dot active region, and Mg-doped GaN contact layer (p-type GaN). The thickness of the active region is well beyond that for conventional quantum-confined structures such as quantum wells, or quantum dots. However, the formation of nanoclusters in ternary InGaN layers leads to charge carrier localization, which may be referred to herein as a quantum dot.

Prior to the epitaxy of N-polar InGaN nanowires, Si-doped N-polar GaN templates, with thicknesses of e.g., about 0.8 μm, were first grown on a sapphire substrate utilizing a Veeco GENxplor plasma-assisted molecular beam epitaxial (PA-MBE) system. The template may be a planar layer. The grown N-polar GaN substrate was then coated with a 10 nm thick Ti layer, which was patterned with electron beam lithography and dry etching to define the nanowire openings for selective area epitaxy. The resulting holes in the Ti layer thus define or establish the locations for the nanowires. The patterned substrate was then loaded into a Veeco Gen 930 PA-MBE system for the subsequent nanowire growth. The nanowires started with an initial 500 nm thick n-GaN section, grown at a thermocouple temperature of about 880° C., with a nitrogen flow of 0.7 sccm and a Ga metal flux of about 3×10⁻⁷ Torr beam equivalent pressure (BEP). For the InGaN quantum dot active region, the growth temperature was reduced to about 650° C. and the nitrogen flow increased to 1.4 sccm. An optimized growth temperature, higher nitrogen flow rate and properly tuned In/Ga flux ratio were found essential to enhance indium incorporation to achieve bright deep visible light emission. The In and Ga BEP are approximately 1×10⁻⁷ Torr and 4×10⁻⁸ Torr, respectively, which can be further varied to tune the emission wavelengths. A p-GaN layer having a thickness of about 100 nm was subsequently grown. Shown in FIG. 2, part (b), the N-polar nanowires show good selectivity and flat c-plane morphology. The realization of uniform N-polar InGaN/GaN nanowire arrays is further illustrated in FIG. 2, part (c).

Other III-nitride materials may be used in the nanostructures. For example, the active region may be composed of, or otherwise include, AlGaN or AlInGaN. The other segments of the heterostructure are also not limited to GaN. The segments may be composed of, or otherwise include, for instance, AlN and AlGaN.

Attaining efficient long wavelength emission, e.g., orange and red, for InGaN-based LEDs is extremely difficult due to the large lattice mismatch (up to 11%) between InN and GaN, indium phase separation, and quantum-confined Stark effect. In this study, to achieve red emission, we have performed a detailed investigation of the role of In/Ga flux ratio, the growth temperature for the quantum dot active region, and the in situ annealing of the active region. With reducing growth temperature, the emission wavelengths showed a progressive shift toward longer wavelengths. However, the emission intensity showed a significant reduction with reducing growth temperature. Moreover, it has remained difficult to achieve spectrally pure red emission (>620 nm). Through detailed growth optimization, it was observed that reduction of Ga flux in the active region leads to a more significant red-shift in emission as opposed to reducing the growth temperature. Variations of the photoluminescence emission spectra were measured for calibration samples grown with various Ga fluxes and nitrogen flow rates. The progressive red-shift with reducing Ga flux can be well explained by the larger bond strength of GaN as compared to InN, which results in the favorable incorporation of Ga in the crystal. Given the growth was performed under nitrogen-rich conditions, a significant impact of nitrogen flow on alloy composition was not observed.

The use of a relatively low growth temperature and high nitrogen flow rate in enhancing indium incorporation and achieving red emission also promotes the formation of point defects, e.g., Ga/In vacancies and N-interstitials, which severely limit the radiative efficiency. In this regard, to further improve the luminescence efficiency, an in situ annealing process is used for the InGaN quantum dot active region. Following the growth of the InGaN dot and a GaN capping layer, a growth interruption was introduced. During the growth interruption, the substrate temperature was raised up under nitrogen soak, and the sample was annealed in situ at an elevated temperature, e.g., about 700° C. for 3 mins. The temperature and duration of the anneal procedure may vary in other cases.

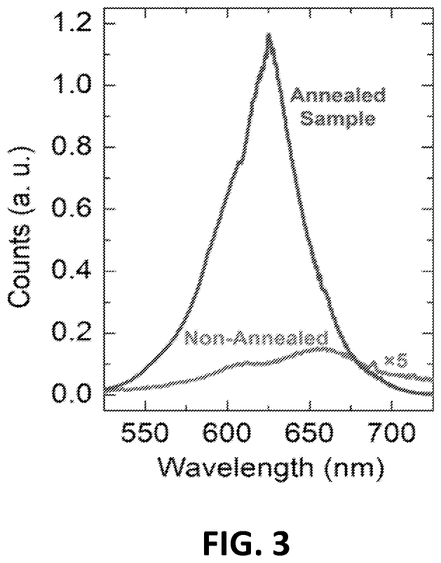

This in situ annealing process improves the optical properties of the devices. Shown in FIG. 3, with the incorporation of the in situ annealing, the photoluminescence intensity is enhanced by more than one order of magnitude. The annealing duration and temperature play a useful role. While a higher annealing temperature is more effective in reducing point defect distribution, it can also result in significant blueshift. To minimize indium out-diffusion during the annealing process, the thickness of GaN capping layer may be selected accordingly. Two example structures with emission wavelengths of about 620 and 635 nm were grown, which are referred to herein as Device A and Device B, respectively.

A cross-sectional specimen for scanning transmission electron microscopy (STEM) study was made from a nanowire LED example using an in situ focused ion beam (FIB) lift-out method performed in a Thermo-Fisher Helios G4 Xe plasma FIB/SEM. A JEOL-JEM3100R05 transmission electron microscope, equipped with double-aberration correctors, was used for imaging the microstructures of the specimen at high spatial resolution. The microscope was operated at 300 keV in STEM mode with lens settings that define a probe smaller than 0.1 nm. High-angle annular dark-field (HAADF) imaging was performed together with bright-field (BF) imaging simultaneously. A Thermo-Fisher Talos F200 STEM/TEM with 4 SDD detectors attached was used for STEM SI using X-ray signals.

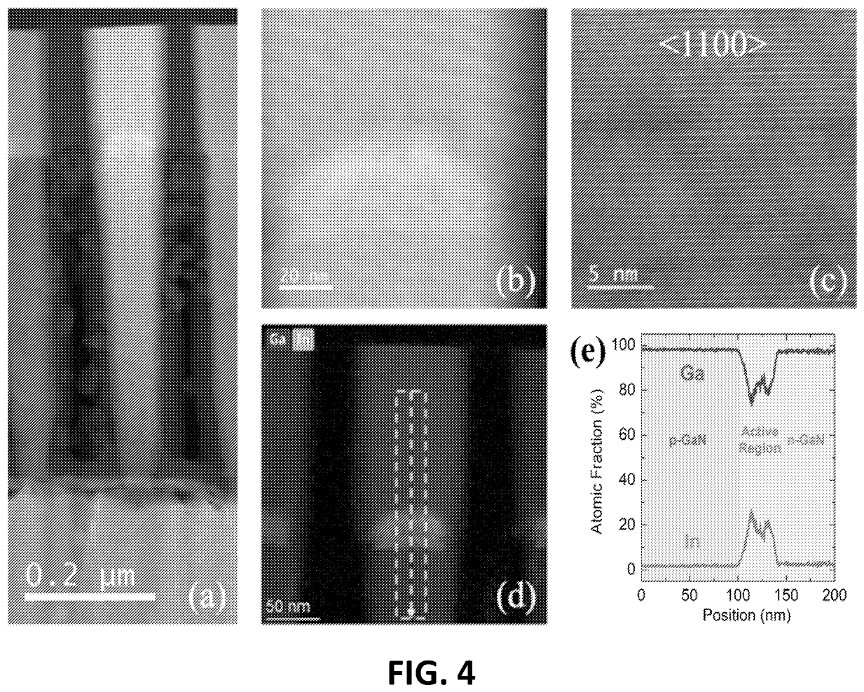

FIG. 4, part (a), is a low magnification STEM-HAADF image showing the cross-section of a few nanowires. No extended crystal defects are observed in the images of the nanowires. The InGaN active region (shown as the region with a lighter contrast in the middle of the nanowire) grows axially along the c-plane of the nanowire, which is in contrast to the growth along the semi-polar planes observed in Ga-polar nanowires. While little lateral growth is observed in the nanowires until the start of the active region, following it there is a noticeable change in nanowire diameter, which is related to the strain relaxation and relatively low growth temperature for this section. The images of the nanowire arrays also show the presence of voids formed in between the nanowires, which are a result of the deposition of insulating layers to electrically isolate the nanowires.

A magnified STEM-HAADF image of the InGaN active region within the nanowire in the center of FIG. 4, part (a), is shown in FIG. 4, part (b), and its atom-resolved HAADF image in FIG. 4, part (c). A relatively inhomogeneous InGaN segment is observed, which may be a direct consequence of the composition-pulling effect previously observed in high In composition InGaN layers. In addition, the in situ thermal annealing process may contribute to the interface diffusion of indium atoms. FIG. 4, part (d), shows Ga and In distributions inside part of the nanowire including the InGaN active region. The In and Ga elemental distributions along the outlined dotted band shown in FIG. 4, part (d), are quantified in FIG. 4, part (e), confirming the formation of the In-rich InGaN active region.

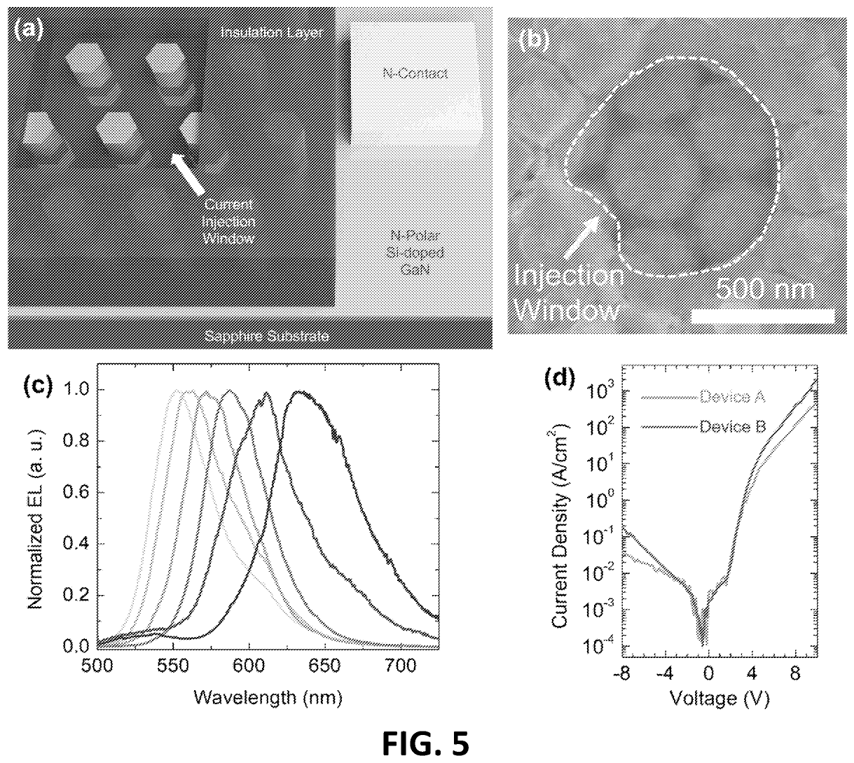

The example micro-LED devices based on the N-polar InGaN nanowires were then fabricated. The nanowire arrays were passivated with an insulating Al₂O₃ layer deposited by atomic layer deposition. An etch-back step was performed to expose the top p-GaN contact layer of the nanowires. Each example was coated with a 300 nm thick SiO₂ layer using plasma-enhanced chemical vapor deposition. Lithography was used to define sub-micron current-injection vias and n-contact windows, followed by the removal of the SiO₂ layer using reactive ion etching. The sub-micron openings varied in lateral dimensions of 750 nm to 1 μm, and a schematic of the current-injection window is shown in FIG. 5, part (a). Shown in FIG. 5, part (b), is a SEM image of a submicron-scale device injection opening, consisting of 5 nanowires, which is the smallest red LED device to our knowledge. The injection window is marked with dashed curves, corresponding to the via opened in the insulation layer. An n-metal contact composed of, or otherwise including, Ti (20 nm)/Au (100 nm) was deposited on the Si-doped N-polar GaN template. A p-type contact to the top of the nanowires included a Ni (5 nm)/Au (5 nm)/Indium tin oxide (180 nm) stack. The contacts were annealed at 550° C. for 1 min in an ambient of forming gas. The fabricated micro-LED devices were configured to emit from the back of the substrate (through the sapphire). To maximize light extraction, the device contacts were covered with a reflective electrode including Ag (50 nm)/Al (100 nm)/Ni (20 nm)/Au (50 nm). Subsequently, the micro-LEDs were characterized directly on wafer without any packaging.

Shown in FIG. 5, part (c), depending on the growth conditions and nanowire sizes, electroluminescence (EL) emission in the wavelength range from about 550 nm to about 650 nm were measured. Devices A and B from the optimized samples were further studied. Shown in FIG. 5, part (d), the devices exhibit similar J-V characteristics, reaching a current density of about 10 A/cm² at a voltage of about 4 V. The reverse bias current is extremely low, suggestion the formation of a well-defined p-n junction. The turn-on voltage for the devices may be further improved through optimization of the p-type contact and device fabrication process.

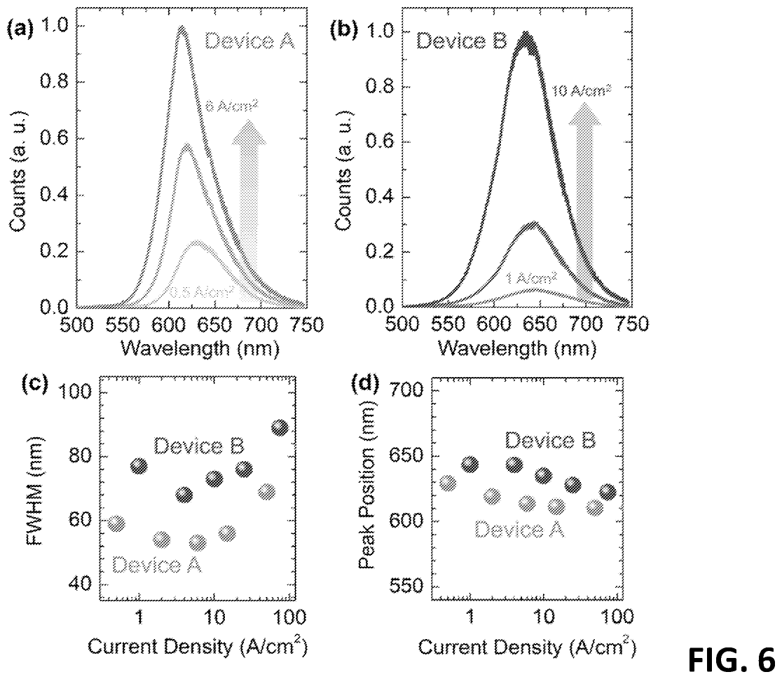

EL spectra of the devices were thereafter measured at room-temperature. FIG. 6, part (a), shows the EL spectra for device A at injection currents from 0.5 to 6 A/cm², with the main peak located at about 620 nm. The emission spectra of device B (peak emission at about 635 nm) are shown in FIG. 6, part (b). The relatively broad emission is due to the compositional non-uniformity in the active region, which has been commonly seen for In-rich InGaN structures. FIGS. 6, parts (c) and (d), plot the variation of the full-width half-maximum (FWHM) and peak position, respectively, for devices A and B. Generally, a trend of larger FWHM is observed at higher injection currents, and for the devices with longer emission wavelengths. The initial decrease in the measured FWHM may be related to the saturation of carriers in deep states that are present in the InGaN layer. The devices also exhibit a blue-shift with increasing injection, due to the quantum-confined Stark effect (QCSE) from the polarization field in the materials, with the emission peak varying by up to about 20 nm for all the grown samples. The energy shift between EL peaks at low current injection and high current injection are approximately 61 meV and 73 meV for device A and B, respectively. These correspond to polarization fields with a strength of about 14.5 kV/cm and about 40.5 kV/cm within the active region for devices A and B, respectively. These values are significantly lower than the expected polarization fields of about 2 MV/cm for fully strained In_{0.4}Ga_{0.6}N with GaN barriers, suggesting some degree of strain relaxation within the active region. The presence of compositional inhomogeneity within the InGaN segments of the nanowires, confirmed by STEM imaging, can also aid localization of carriers, reducing the effect of the polarization fields.

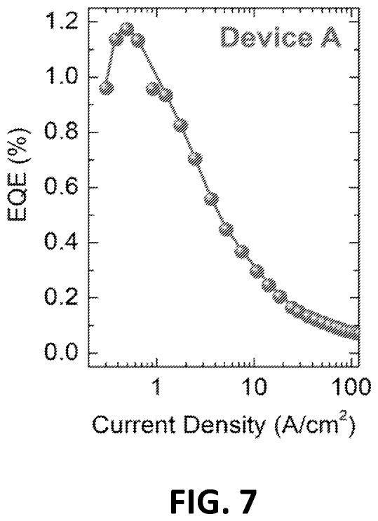

The measured EQE at different injection currents is plotted for device A in FIG. 7. The EQE shows a peak at relatively low current densities of about 0.5 A/cm². For comparison, previously reported InGaN red-emitting quantum well LEDs exhibit efficiency peak at current densities about 0.8 to 15 A/cm². It is generally observed that the peak efficiency occurs at a lower current density level for LED heterostructures with a lower level of Shockley-Read-Hall (SRH) non-radiative recombination. This suggests that the InGaN nanowire micro-LED devices disclosed herein have significantly reduced defects and dislocations, compared to conventional InGaN quantum wells, due to the efficient surface strain relaxation as well as the use of improved epitaxy process and in situ annealing to reduce point defect formation. Recent studies further suggested that the sidewall of N-polar InGaN nanowires was characterized by the presence of N-rich clusters, which can further help minimize surface oxidation and impurity incorporation, thereby reducing nonradiative surface recombination. Efficiency droop, however, is measured with increasing injection current. Similar effects were also observed for device B. Efficiency droop has been commonly measured in GaN-based LEDs, with the underlying causes including Auger recombination, electron overflow, and carrier delocalization. Recent studies of tunnel junction based blue LEDs suggested efficiency droop can be significantly reduced by enhancing charge carrier (hole) injection into the device active region, suggesting electron overflow is the primary cause for the observed efficiency droop. In this regard, the carrier leakage, electron overflow and efficiency droop can be reduced by incorporating a core-shell heterostructure surrounding the device active region and suitable electron blocking layer.

Red-emitting N-polar InGaN nanowire heterostructures have been fabricated to realize the smallest size red-emitting LED devices. An external quantum efficiency of about 1.2% was measured directly on wafer, which is significantly higher than that of conventional InGaN quantum well based micro-LEDs operating in this wavelength range. Detailed studies further suggest that the performance is largely limited by severe efficiency droop, due to electron overflow, which can be addressed by improving the device design and epitaxy process. This work provides a path to overcome the efficiency cliff of deep visible micro-LEDs that are relevant for a broad range of applications including mobile displays and virtual/augmented reality devices and systems.

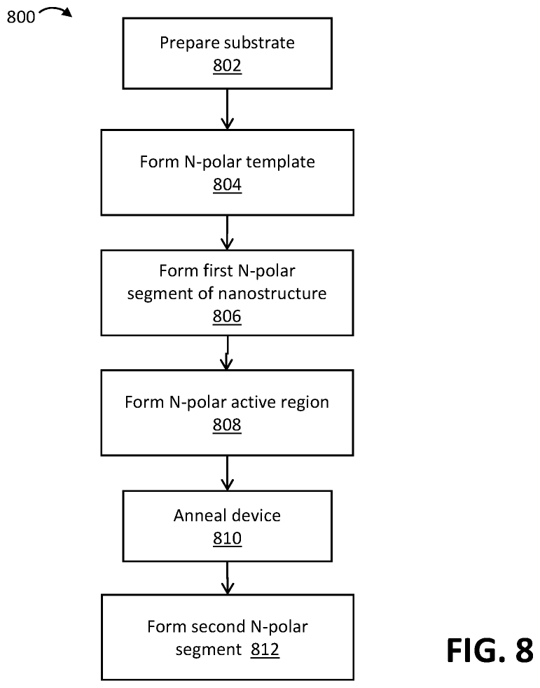

FIG. 8 depicts a method 800 of fabricating a device in accordance with one example. The method 800 may be used to manufacture any of the devices described herein or another device. The method 800 may include additional, fewer, or alternative acts. For instance, the method 800 may or may not include one or more acts directed to preparing a substrate.

The method 800 may begin with an act 802 in which a substrate is prepared or otherwise provided. The substrate may be composed of, or otherwise include, sapphire. Additional or alternative materials may be used, including, for instance, Si, SiC, and various metal templates/substrates.

In some cases, the act 802 includes a wet or other etch procedure. Alternatively or additionally, the act 802 may include implementation of a substrate cleaning procedure. Fewer, additional or alternative acts may be implemented to prepare the substrate.

The method 800 includes an act 804 in which a nitrogen-polar (N-polar) template is formed on the substrate. The N-polar template may be composed of, or otherwise include, Si-doped N-polar GaN. Additional or alternative materials may be used, including, for instance, Si-doped InGaN and Si-doped AlGaN. The act 804 may include the growth of a planar layer and subsequent patterning thereof, as described above.

The method 800 includes an act 806 in which a first N-polar, III-nitride semiconductor segment of a nanostructure is formed. The first N-polar, III-nitride semiconductor segment is supported by (e.g., in contact with) the N-polar template. As described above, the first N-polar, III-nitride semiconductor segment may be configured as an n-type contact layer. The first N-polar, III-nitride semiconductor segment may be composed of, or otherwise include, Si-doped GaN. Alternative or additional n-type doped semiconductor materials may be used, including, for instance, AlN or AlGaN, and alloys thereof.

The method 800 includes an act 808 in which a N-polar active region of the nanostructure is formed. As described above, the N-polar active region is supported by (e.g., in contact with) the first N-polar, III-nitride semiconductor segment, and the N-polar active region includes a ternary or quaternary III-nitride semiconductor material, As described herein, the ternary or quaternary III-nitride semiconductor material may be InGaN, but other materials may be used, including, for instance, AlGaN or AlInGaN, and alloys thereof. Growing the N-polar active region may include implementing a growth procedure configured such that the N-polar active region has red spectrum emission.

In the example of FIG. 8, the method 800 includes annealing the N-polar active region after growing the second N-polar, III-nitride semiconductor segment in an act 810. The annealing of the N-polar active region may be implemented in a chamber in which the other portions of the nanostructure are grown (e.g., the first N-polar, III-nitride semiconductor segment, the N-polar active region, and the second N-polar, III-nitride semiconductor segment). Annealing the active region may thus be implemented without removal from a growth chamber in which the active region, and a second III-nitride semiconductor segment, are grown.

The method 800 includes an act 812 in which a second N-polar, III-nitride semiconductor segment of the nanostructure is grown. As described herein, the second N-polar segment may be configured as a contact layer supported by (e.g., in contact with) the N-polar active region. In some cases, the second N-polar, III-nitride semiconductor segment is composed of, or otherwise includes, Mg-doped GaN. Additional or alternative p-type doped semiconductor materials may be used, including, for instance, AlN or AlGaN, and alloys thereof.

In some cases, the first N-polar, III-nitride semiconductor segment, the N-polar active region, and the second N-polar, III-nitride semiconductor segment are grown under nitrogen-rich conditions, as described above.

The method 800 may include any number of additional acts. For instance, the nanostructures may be passivated via the deposition of one or more insulating layers (e.g., an Al₂O₃ layer). Further acts may be directed to defining current-injection vias as well as p-contact and n-contact windows, and forming n-metal and p-metal contacts.

Described above are high efficiency, high brightness, and robust micro or sub-microscale red light emitting diode (LED) devices. The devices may be useful in emerging virtual reality and future ultrahigh resolution mobile displays. For the first time, a N-polar InGaN nanowire sub-microscale LED devices emitting in the red spectrum has been realized. The disclosed devices can overcome the efficiency cliff of conventional red-emitting micro-LEDs. The emission wavelengths of N-polar InGaN nanowires can be progressively shifted from yellow to orange and red, which is difficult to achieve for conventional InGaN quantum wells or Ga-polar nanowires. The optical emission intensity can be enhanced by more than one order of magnitude by employing an in situ annealing process of the InGaN active region, leading to significantly reduced defect formation. In some cases, the LED devices have lateral dimensions as small as about 0.75 μm, and include about 5 InGaN nanowires. The disclosed devices are the smallest red-emitting LEDs ever realized. A maximum external quantum efficiency of about 1.2% was measured, which is nearly one order of magnitude higher than conventional quantum well based micro-LEDs operating in this wavelength range.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A method for fabricating a light emitting diode (LED) device, the method comprising:
forming a nitrogen-polar (N-polar) template on a substrate;
growing a first N-polar, III-nitride semiconductor segment of a nanostructure;
growing a N-polar active region of the nanostructure, the N-polar active region being supported by the first N-polar, III-nitride semiconductor segment, the N-polar active region comprising a ternary or quaternary III-nitride semiconductor material; and
growing a second N-polar, III-nitride semiconductor segment of the nanostructure, the second N-polar segment being supported by the N-polar active region.

2. The method of claim 1, further comprising annealing the N-polar active region after growing the second N-polar, III-nitride semiconductor segment.

3. The method of claim 2, wherein growing the N-polar active region comprises implementing a growth procedure configured such that the N-polar active region comprises an N-polar quantum well, an N-polar quantum disk, or an N-polar quantum dot, that emits in the red spectrum.

4. The method of claim 2, wherein annealing the N-polar active region is implemented in a chamber in which the first N-polar, III-nitride semiconductor segment, the N-polar active region, and the second N-polar, III-nitride semiconductor segment are grown.

5. The method of claim 1, wherein growing the first N-polar, III-nitride semiconductor segment, growing the N-polar active region, and growing the second N-polar, III-nitride semiconductor segment are performed under nitrogen-rich conditions.

6. The method of claim 1, wherein growing the N-polar active region comprises implementing a growth procedure configured such that the N-polar active region has red spectrum emission.

7. The method of claim 1, wherein the ternary or quaternary III-nitride semiconductor material is InGaN.

8. A method for fabricating a light emitting diode (LED) device, the method comprising:
growing a first III-nitride semiconductor segment;
growing an active region supported by the first III-nitride semiconductor segment, the active region comprising a ternary or quaternary III-nitride semiconductor material;
growing a second III-nitride semiconductor segment, the second III-nitride semiconductor segment being supported by the active region; and
annealing the active region after growing the second III-nitride semiconductor segment.

9. The method of claim 8, wherein growing the active region comprises implementing a growth procedure configured such that the active region comprises an N-polar quantum well, an N-polar quantum disk, or an N-polar quantum dot, that emits in the red spectrum.

10. The method of claim 8, wherein annealing the active region is implemented without removal from a growth chamber in which the active region and the second III-nitride semiconductor segment are grown.

11. The method of claim 8, wherein growing the first III-nitride semiconductor segment, growing the active region, and growing the second III-nitride semiconductor segment are performed under nitrogen-rich conditions.

12. The method of claim 8, wherein growing the active region comprises implementing a growth procedure configured such that the active region has red spectrum emission.

13. The method of claim 8, wherein the ternary or quaternary III-nitride semiconductor material is InGaN.

14. A light emitting diode (LED) device comprising:
a substrate;
an N-polar, III-nitride template supported by the substrate; and
a nanostructure extending outward from the substrate and supported by the N-polar, III-nitride template;
wherein the nanostructure comprises:
a first N-polar, III-nitride semiconductor segment;
a N-polar active region supported by the first N-polar, III-nitride semiconductor segment, the N-polar active region comprising a ternary or quaternary III-nitride semiconductor material; and
a second N-polar, III-nitride semiconductor segment supported by the N-polar active region.

15. The LED device of claim 14, wherein the first N-polar, III-nitride semiconductor segment and the second N-polar, III-nitride semiconductor segment comprise N-polar GaN.

16. The LED device of claim 14, wherein the ternary or quaternary III-nitride semiconductor material is InGaN.

17. The LED device of claim 14, wherein the ternary or quaternary III-nitride semiconductor material is InGaN with an indium composition greater than about 0.20.

18. The LED device of claim 14, wherein the N-polar active region is configured for red spectrum emission.

19. The LED device of claim 14, wherein the nanostructure has sub-micron lateral dimensions.

20. A light emitting diode (LED) device comprising:
a substrate;
an N-polar, III-nitride template; and
a nanostructure supported by, and extending outward from, the substrate, the nanostructure comprising:
a first N-polar, III-nitride semiconductor segment;
a N-polar active region supported by the first N-polar, III-nitride semiconductor segment, the N-polar active region comprising a ternary or quaternary III-nitride semiconductor material; and
a second N-polar, III-nitride semiconductor segment supported by the N-polar active region,
wherein the N-polar active region has a thickness too large for formation of a quantum well.

21. The LED device of claim 20, wherein the thickness is greater than a range from about 3 nm to about 5 nm.

22. A light emitting diode (LED) device comprising:
a substrate; and
a nanostructure supported by, and extending outward from, the substrate, the nanostructure comprising an active region, the active region being configured for red spectrum emission;
wherein the nanostructure has sub-micron lateral dimensions.

23. The LED device of claim 22, wherein the active region comprises a ternary or quaternary III-nitride semiconductor material.

24. The LED device of claim 22, further comprising an N-polar, III-nitride template disposed between the substrate and the nanostructure.
